(19) United States
(12) Patent Application Publication
(10) Pub. No.: US 2013/0220221 A1
(43) Pub. Date: Aug. 29, 2013

(54) METHOD AND APPARATUS FOR PRECURSOR DELIVERY

(71) Applicant: Applied Materials, Inc., (US)

(72) Inventors: ERROL ANTONIO C. SANCHEZ, Tracy, CA (US); MARCEL E. JOSEPHSON, San Jose, CA (US); JAIDEV RAJARAM, Bangalore (IN); RICHARD O. COLLINS, Santa Clara, CA (US); DAVID K. CARLSON, San Jose, CA (US)

(73) Assignee: APPLIED MATERIALS, INC., Santa Clara, CA (US)

(21) Appl. No.: 13/769,912

(22) Filed: Feb. 19, 2013

Related U.S. Application Data
(60) Provisional application No. 61/602,184, filed on Feb. 23, 2012.

(51) Int. Cl. C23C 16/455

(52) U.S. Cl. CPC C23C 16/455
USPC 118/712; 118/726; 137/334; 137/1

(57) ABSTRACT

Methods and apparatus for delivering a gas mixture to a process chamber are provided herein. In some embodiments, a precursor delivery apparatus may include an ampoule having a body with a first volume to hold a liquid precursor, an inlet to receive the liquid precursor and a carrier gas, and an outlet to flow a gas mixture of the liquid precursor and the carrier gas from the ampoule; a first heater disposed proximate to or in the first volume to heat the liquid precursor disposed in the first volume proximate to or at a first location within the first volume where the liquid precursor contacts the carrier gas; and a heat transfer apparatus disposed about the body to at least one of provide heat to or remove heat from the ampoule.

### CROSS-REFERENCE TO RELATED APPLICATIONS

This application claims benefit of U.S. provisional patent application Ser. No. 61/602,184, filed Feb. 23, 2012, which is herein incorporated by reference.

### FIELD

Embodiments of the present invention generally relate to substrate processing, and more specifically, to methods and apparatus for delivering a gas mixture to a process chamber.

### BACKGROUND

Chemical vapor deposition (CVD) processes can be used to deposit thin films or the like. In liquid reactant CVD systems, a carrier gas may be bubbled through a container of a liquid precursor to form a gas mixture. The mixture may then be transported to the process chamber to be used in a substrate process. The delivery method may involve an ampoule, where the carrier gas is flowed through a heated liquid precursor residing in the ampoule to form the gas mixture. Dynamic control of the liquid precursor condition within the ampoule is not possible in a timeframe, such as during a processing run between the exchange of substrates or the like. Accordingly, to adjust a parameter, such as the temperature, volume, or concentration of the liquid precursor in the ampoule, the processing system must be taken offline, for example, to replace the ampoule or to bring the temperature of the liquid precursor up to a suitable temperature for operation.

Accordingly, the inventors have provided improved methods and apparatus for delivering a gas mixture to a process chamber.

### SUMMARY

Methods and apparatus for delivering a gas mixture to a process chamber are provided herein. In some embodiments, a precursor delivery apparatus may include an ampoule having a body with a first volume to hold a liquid precursor, an inlet to receive the liquid precursor and a carrier gas, and an outlet to flow a gas mixture of the liquid precursor and the carrier gas from the ampoule; a first heater disposed proximate to or in the first volume to heat the liquid precursor disposed in the first volume proximate to or at a first location within the first volume where the liquid precursor contacts the carrier gas; and a heat transfer apparatus disposed about the body to at least one of provide heat to or remove heat from the ampoule.

In some embodiments, a system for processing a substrate using a precursor delivery apparatus may include a process chamber for processing a substrate; an ampoule having a body with a first volume to hold a liquid precursor, an inlet to receive the liquid precursor and a carrier gas, and an outlet to flow a gas mixture of the liquid precursor and the carrier gas from the ampoule, wherein the outlet is coupled to the process chamber to deliver the gas mixture from the ampoule to an inner volume of the process chamber; a first heater disposed proximate to or in the first volume to heat the liquid precursor disposed in the first volume proximate to or at a location within the first volume where the liquid precursor contacts the carrier gas; a heat transfer apparatus disposed about the body to at least one of provide heat to or remove heat from the ampoule; a liquid precursor source coupled to the inlet of the ampoule to provide the liquid precursor to the ampoule without disconnecting the ampoule from the process chamber; and a carrier gas source coupled to the inlet of the ampoule to provide the carrier gas, wherein the liquid precursor and the carrier gas are coupled to the inlet in a manner to alternately supply the liquid precursor and the carrier gas to the inlet of the ampoule.

In some embodiments, a method of delivering a gas mixture to a process chamber may include flowing a carrier gas through a liquid precursor disposed in a first volume of an ampoule coupled to the process chamber to form a gas mixture and to deliver the gas mixture to the process chamber; and adjusting one or more parameters in the ampoule to control the formation of the gas mixture within a timeframe of a substrate transfer in the process chamber during a process run without removing the ampoule.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIGS. 1A-1B respectively depict a perspective view and a schematic side view of an ampoule in accordance with some embodiments of the present invention.

FIG. 2 depicts a schematic view of a precursor delivery apparatus in accordance with some embodiments of the present invention.

FIG. 3 depicts a flow chart of a method for delivering a gas mixture to a process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for delivering an evaporated mixture to a process chamber are provided herein. The inventive methods and apparatus advantageously facilitate dynamic control of a liquid precursor in an ampoule, e.g., a bubbler, such that consistent, repeatable delivery of a gas mixture having a desired concentration can be provided to a substrate processing system.

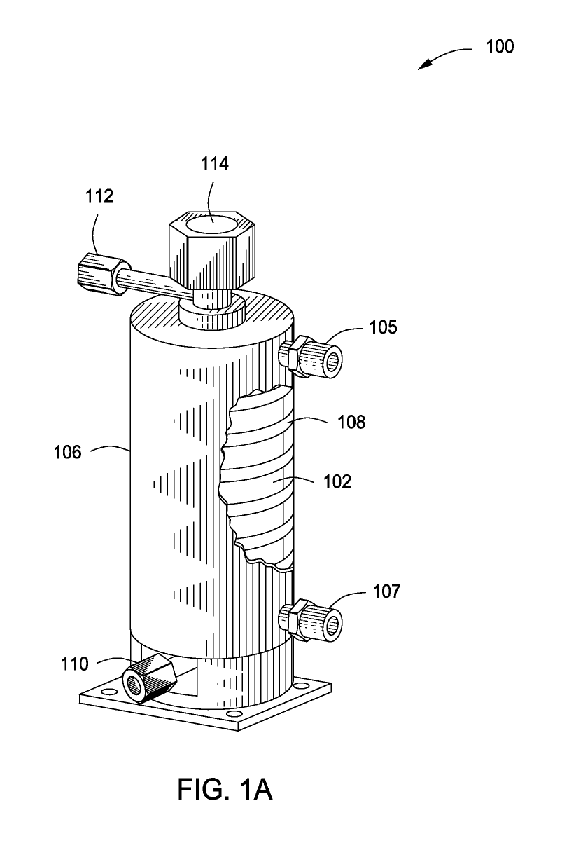

FIGS. 1A and 1B depict a schematic side view of an ampoule 100 in accordance with some embodiments of the present invention. In some embodiments, the ampoule comprises a body 102 having a first volume 104 to hold a liquid precursor therein. In some embodiments, the body 102 is made of stainless steel. In some embodiments, the first volume 104 may range from about 100 cubic centimeters (cm³) to about 200 cm³. A heater 103 (e.g., a first heater) may be disposed proximate to or in the first volume 104 to heat the liquid precursor when disposed in the first volume 104. The heater 103 may be disposed below the first volume 104 as shown. Alternatively, the heater 103 may be located within the first volume 104 or about the first volume 104 proximate the liquid precursor.

In some embodiments, the ampoule 100 includes a heat transfer apparatus 106 disposed about the body 102 to at least one of provide heat to or remove heat from the ampoule 100. Exemplary heat transfer apparatus may include a heating jacket, or the like, such as for circulating a heat transfer medium therethrough. As illustrated in FIGS. 1A-1B, the heat transfer apparatus 106 may include one or more conduits 108 disposed in or adjacent to the body 102 of the ampoule 100 to flow a heat transfer medium therethrough. As illustrated, the one or more conduits 108 may include an inlet 105 and an outlet 107 to receive and return the heat transfer medium. Exemplary heat transfer media may include one or more of deionized water, GALDEN® heat transfer fluids, or the like. In some embodiments, an external surface of the heat transfer apparatus 106 may be insulated by a plastic powder coated thermal insulation.

The ampoule 100 may include an inlet 110, to receive a liquid precursor and a carrier gas, and an outlet 112 to flow a gas mixture of the liquid precursor and the carrier gas from the ampoule 100. The inlet 110 and outlet 112 may be fluidly coupled to the first volume 104.

A central port 114 may be coupled to the body 102. The central port 114 may include, and/or facilitate the introduction thereof to the first volume 104, a liquid precursor level sensor 113 to measure the level of the liquid precursor in the first volume 104. The central port 114 may include and/or facilitate the introduction thereof to the first volume 104, a thermocouple 115 to measure a temperature in the first volume 104.

A fritted disk 116 may be disposed in the first volume 104 of the body 102 between the inlet 110 and the outlet 112. The fritted disk 116 may facilitate uniform and maximum contact between the bubbled carrier gas and the liquid precursor in the ampoule 100. Further embodiments of the fritted disk 116 are set forth in U.S. Pat. No. 7,969,911, Jun. 28, 2011, “Apparatus and methods for chemical vapor deposition” assigned to the assignee of the present invention, and which is incorporated herein by reference.

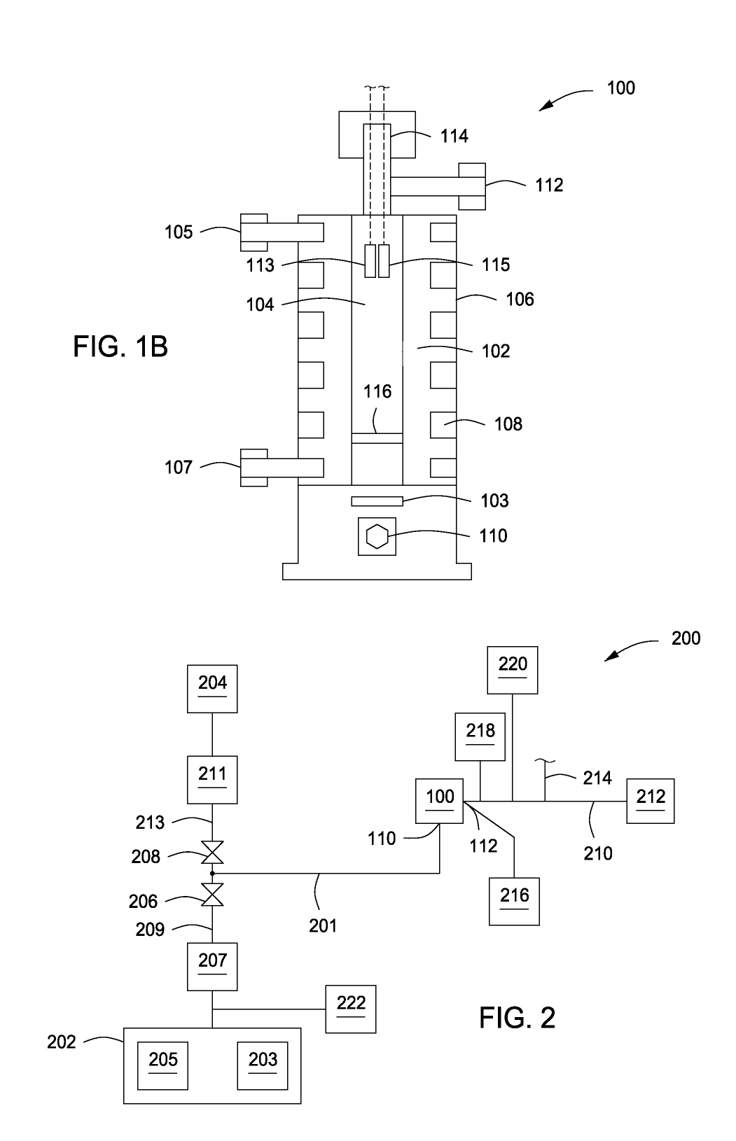

FIG. 2 depicts a schematic view of a precursor delivery apparatus in accordance with some embodiments of the present invention. The precursory delivery apparatus 200 may include the ampoule 100 as described above. The apparatus 200 may include a liquid precursor source 202 to provide the liquid precursor and a carrier gas source 204 to provide the carrier gas to the inlet 110 of the ampoule 100. The liquid precursor source 202 may include a solute source 203, such as including a concentrated form of the liquid precursor, and a solvent source 205, such as including a solvent to dilute the liquid precursor. The solute and solvent sources 203, 205 may separately provide solute and solvent respectively to the first volume 104 of the ampoule 100. Alternatively, the solute and solvent may be pre-mixed prior to arriving at the inlet 110 of the ampoule 100. Similarly, the carrier gas source 204 may provide one or more carrier gases, which may be pre-mixed prior to arriving at the inlet 110 or provided individually to the inlet 110 of the ampoule 100.

As illustrated in FIG. 2, the liquid precursor source 202 and the carrier gas source 204 may be coupled to the inlet 110 of the ampoule 100 via a conduit 201. The liquid precursor source 202 and the carrier gas source 204 may be coupled to the inlet 110 such that the liquid precursor and the carrier gas may be alternately supplied to the ampoule 100 as discussed below.

For example, a first valve 206 may be disposed between the liquid precursor source 202 and the inlet 110 of the ampoule 100. In some embodiments a heater 207 (e.g., a second heater) may be disposed proximate a conduit 209 coupling the liquid precursor source 202 to the first valve 206. Similarly, a second valve 208 may be disposed between the carrier gas source 204 and the inlet 110 of the ampoule 100. In some embodiments, a heater 211 (e.g., a third heater) may be disposed proximate a conduit 213 coupling the carrier gas source 204 to the second valve 208. A liquid flow meter 222 may be disposed between the liquid precursor source 202 and the inlet 110 of the ampoule 100 as shown. Alternatively, the liquid flow meter 222 may be disposed at any suitable location between the liquid precursor source 202 and the inlet 110, such as at any suitable location along the conduit 209 or conduit 201.

The first valve 206 and the second valve 208 may be selectively opened and closed to allow an alternating supply of carrier gas and liquid precursor to the inlet 110 of the ampoule 100, such as via the conduit 201 as illustrated. The liquid precursor level sensor may control the operation of the first valve 206 and the second valve 208. In some embodiments, such as to replenish or maintain the volume of liquid precursor in the first volume 104 at a desired level, the liquid precursor level sensor may cause the second valve 208 to close and cause the first valve 206 to open to allow liquid precursor from the liquid precursor source 202 to flow to the first volume 104 of the ampoule 100. In some embodiments, after the volume of liquid precursor in the first volume 104 of the ampoule 100 has been replenished, the liquid precursor level sensor can cause the first valve 206 to close and cause the second valve 208 to open to allow the carrier gas from the carrier gas source 204 to flow to the ampoule 100.

The apparatus 200 may include a deposition line 210 that allows the gas mixture to flow from the outlet 112 of the ampoule 100 to a process chamber 212. A vent line 214 may be coupled to the outlet 112 of the ampoule 100 to relieve pressure in the ampoule 100, for example, such as when liquid precursor is being added to the ampoule 100. For example the vent line 214 and the deposition line 210 may be alternately opened to the outlet 112 via a three-way valve or the like. In some embodiments, a back pressure controller 216 may be coupled to the outlet 112 to maintain a reduced pressure in the first volume 104 of the ampoule 100 ranging from about 200 to about 600 Torr.

The apparatus 200 may include a concentration monitor 218 disposed between the outlet 112 of the ampoule 100 and the deposition and vent lines 210, 214. The concentration monitor 218 may measure the concentration of the gas mixture exiting the outlet 112. The concentration monitor 218 may be operative to adjust one or more of the heaters 103, 207, 211, the heat transfer apparatus 106, liquid precursor source 202, or carrier gas source 204 to control the concentration of the gas mixture exiting the outlet 112.

A second carrier gas source 220 may be disposed between the concentration sensor 218 and the deposition and vent lines 210, 214 to provide a second carrier gas to further dilute the gas mixture that exits the outlet 112 of the ampoule 100 when necessary. Alternatively, the second carrier gas source 220 and the carrier gas source 204 may be the same.

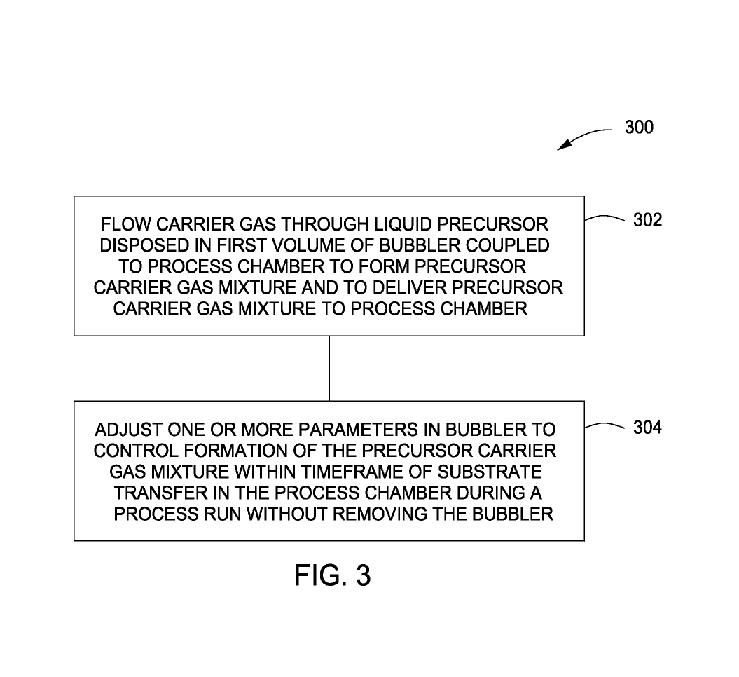

FIG. 3 depicts a flowchart of a method 300 for delivering a gas mixture to a process chamber in accordance with some embodiments of the present invention. The method 300 is described below in accordance with embodiments of the ampoule 100 and the precursor delivery apparatus 200; however, other apparatus may be utilized with the inventive methods discussed below.

In some embodiments, the method 300 may begin when the liquid precursor is present in the first volume 104 of the ampoule 100 at a desired level, e.g., a desired volume level, or within a tolerance of the desired level. The desired level is above the position of the fritted disk 116. Further, the liquid precursor may be heated to a desired temperature suitable for bubbling, such as using one or more of the heater 103, the heat transfer apparatus 106, or the heater 207.

The method 300 generally begins at 302, by flowing the carrier gas through the liquid precursor disposed in the first volume 104 of the ampoule 100 to form a gas mixture and to deliver the gas mixture to the process chamber 212. The carrier gas may be provided by the carrier gas source 204 to the inlet 110 of the ampoule 100. The carrier gas may optionally be heated by the heater 211 prior to entering the ampoule 100.

Exemplary liquid precursors may include solute and solvents. For example, solutes may include one or more of trimethylindium (In(Ch₃)₃), gallium trichloride (GaCl₃), indium trichloride (InCl₃), or the like. Exemplary solvents may include one or more of hexadecane, N,N-dimethyldodecylamine, polyether, or the like. Exemplary carrier gases may include one or more of an inert gas such as hydrogen (H₂) or nitrogen (N₂).

The first volume 104 facilitates instantaneous control over the concentration of the gas mixture exiting the outlet 112. The combination of its small volume, e.g., about 100 cm³ to about 200 cm³′ and one or more of heaters 103, 207, 211, liquid precursor source 202, and carrier gas source 204, enables replenishment of the precursor and/or adjustment of various parameters to consistently reproduce the gas mixture having the desired concentration.

Accordingly, at 304, one or more parameters of the ampoule 100 may be adjusted to control formation of the gas mixture within a timeframe of substrate transfer in the process chamber during a process run without removing the ampoule 100 from the precursor delivery apparatus 200. Exemplary timeframes of substrate transfer may include between transfer of sequential substrates, after processing of several substrates, such about 10 substrates or less, during a chamber clean between processing sequential substrates or several substrates, or the like. The adjustment at 104 is a dynamic process that occurs during a process run, such as when the process chamber 212 is in an operating mode and processing substrates, and not during downtime of the process chamber 212, such as when the chamber 212 is being serviced by an operator. Further, the adjustment at 104 occurs without removing and/or replacing the ampoule 100.

Exemplary parameters in the ampoule 100 that may be adjusted at 104 include one or more of the volume of the liquid precursor within the first volume 104, the temperature of the liquid precursor within the first volume 104, the ambient temperature of the first volume 104, e.g., in a portion of the first volume 104 not occupied by the liquid precursor, concentration of the liquid precursor within the first volume 104, and the like.

For example, in some embodiments, flowing the carrier gas through the first volume at 302 vaporizes the liquid precursor within the first volume 104, accompanied by a fall from its initial temperature. Thus, the amount of energy provided to heat the liquid precursor remaining in the first volume 104 may be adjusted from an initial amount of energy provided to heat the liquid precursor. The adjustment of the energy being provided to heat the liquid precursor remaining in the first volume 104 may be necessary, for example, to maintain the same vaporization rate of the liquid precursor as at the initial level such that the concentration of the gas mixture is reproduced reliably for a subsequent substrate being processed in the chamber 212.

The temperature of the liquid precursor may be adjusted, for example, by adjusting one or more of the heater 103, the heat transfer apparatus 106, or the temperature of the incoming carrier gas, such as using the heater 211.

For example, in some embodiments, flowing the carrier gas through the first volume at 302 vaporizes the liquid precursor as to cause the liquid precursor within the first volume to fall below a desired level. For example, the desired level may be a volume level necessary for optimal carrier gas contact during bubbling Accordingly, the amount of liquid precursor may be replenished to the desired level within the first volume 104, or to within a tolerance range of the desired level.

The volume of the liquid precursor may be adjusted within the first volume 104, for example, by flowing the liquid precursor from the liquid precursor source 202 via the first valve 206 to the inlet 110 of the ampoule 100. Further, the temperature of the liquid precursor—either the fresh liquid precursor being provided to the inlet 110 or the liquid precursor remaining in the first volume 104 prior to replenishment—may be adjusted in combination with replenishment, such as by adjusting one or more of the heaters 103, 207, or the heat transfer apparatus 106 to achieve a desired temperature of the liquid precursor suitable for forming the gas mixture having a desired concentration for processing.

In some embodiments, the liquid precursor may comprise a solute and a solvent. The concentration of the liquid precursor in the ampoule 100 may be monitored directly, or alternatively, indirectly, such as by monitoring a concentration of the precursor liquid carrier gas precursor mixture upon exiting the ampoule 100 via the outlet 112. For example, the solute and the solvent may have different vaporization rates, and the concentration of the liquid precursor, e.g., the concentration of the solute in the solvent, may change. Such a change in concentration may affect the concentration of the gas mixture. Accordingly, in some embodiments, a solute from the solute source 203 and/or a solvent from the solvent source 205 may be provided to replenish the liquid precursor in the first volume 104 to the desired concentration. For example, the solute and solvent may be provided separately, or alternatively, the solute and solvent may be pre-mixed at an appropriate concentration such that, when added to the liquid precursor present in the first volume 104, the desired concentration of the liquid precursor in the first volume 104 is achieved. Similar to embodiments discussed above, the solute and/or solvent may be pre-heated prior to flowing the solute and/or solvent to the ampoule 110, and/or the solute and/or solvent may be heated in situ, such as by the heater 103 and/or the heat transfer apparatus 106, to provide a liquid precursor within the first volume 104 having a desired concentration and/or desired temperature.

While the foregoing is directed to embodiments of the present invention, other and further embodiments of the invention may be devised without departing from the basic scope thereof.

1. A precursor delivery apparatus, comprising:
an ampoule having a body with a first volume to hold a liquid precursor, an inlet to receive the liquid precursor and a carrier gas, and an outlet to flow a gas mixture of the liquid precursor and the carrier gas from the ampoule;
a first heater disposed proximate to or in the first volume to heat the liquid precursor disposed in the first volume proximate to or at a first location within the first volume where the liquid precursor contacts the carrier gas; and
a heat transfer apparatus disposed about the body to at least one of provide heat to or remove heat from the ampoule.

2. The apparatus of claim 1, further comprising:
a liquid precursor source coupled to the inlet of the ampoule to provide the liquid precursor; and
a carrier gas source coupled to the inlet of the ampoule to provide the carrier gas, wherein the liquid precursor and the carrier gas are coupled to the inlet in a manner to alternately supply the liquid precursor and the carrier gas to the inlet of the ampoule.

3. The apparatus of claim 1, wherein the heat transfer apparatus further comprises:
one or more conduits disposed in or adjacent to the body of the ampoule to flow a heat transfer medium therethrough.

4. The apparatus of claim 1, further comprising:
a liquid precursor level sensor coupled to the first volume to measure a level of the liquid precursor in the first volume; and
a thermocouple coupled to the ampoule to measure a temperature in the ampoule.

5. The apparatus of claim 1, further comprising:
a fritted disk disposed at the first location within the first volume of the ampoule to facilitate contact between the liquid precursor when disposed in the first volume and the carrier gas.

6. A system for processing a substrate using a precursor delivery apparatus, comprising:
a process chamber for processing a substrate;
an ampoule having a body with a first volume to hold a liquid precursor, an inlet to receive the liquid precursor and a carrier gas, and an outlet to flow a gas mixture of the liquid precursor and the carrier gas from the ampoule, wherein the outlet is coupled to the process chamber to deliver the gas mixture from the ampoule to an inner volume of the process chamber;
a first heater disposed proximate to or in the first volume to heat the liquid precursor disposed in the first volume proximate to or at a location within the first volume where the liquid precursor contacts the carrier gas;
a heat transfer apparatus disposed about the body to at least one of provide heat to or remove heat from the ampoule;
a liquid precursor source coupled to the inlet of the ampoule to provide the liquid precursor to the ampoule without disconnecting the ampoule from the process chamber; and
a carrier gas source coupled to the inlet of the ampoule to provide the carrier gas, wherein the liquid precursor and the carrier gas are coupled to the inlet in a manner to alternately supply the liquid precursor and the carrier gas to the inlet of the ampoule.

7. The system of claim 6, further comprising:
a concentration sensor disposed between the outlet of the ampoule and the process chamber to monitor a concentration of the gas mixture that exits the outlet of the ampoule; and
a second carrier gas source disposed between the concentration sensor and process chamber to selectively provide a second carrier gas to dilute the gas mixture.

8. The system of claim 6, wherein the heat transfer apparatus further comprises one or more conduits disposed in or adjacent to the body of the ampoule to flow a heat transfer medium therethrough, and further comprising:
a heat transfer medium source coupled to the one or more conduits to circulate a heat transfer medium through the one or more conduits.

9. The system of claim 6, further comprising:
a liquid precursor level sensor coupled to the first volume to measure a level of the liquid precursor in the first volume; and
a thermocouple coupled to the ampoule to measure a temperature in the ampoule.

10. The system of claim 6, wherein the liquid precursor source further comprises:
a solute source to provide a solute to the ampoule; and
a solvent source to provide a solvent to the ampoule.

11. The system of claim 6, further comprising:
a second heater disposed between the liquid precursor source and the ampoule to heat a liquid precursor provided by the liquid precursor source prior to entering the ampoule; and
a third heater disposed between the carrier gas source and the ampoule to heat a carrier gas provided by the carrier gas source prior to entering the ampoule.

12. A method of delivering a gas mixture to a process chamber, comprising:
flowing a carrier gas through a liquid precursor disposed in a first volume of a ampoule coupled to the process chamber to form a gas mixture and to deliver the gas mixture to the process chamber; and
adjusting one or more parameters of the ampoule to control the formation of the gas mixture within a timeframe of a substrate transfer in the process chamber during a process run without removing the ampoule.

13. The method of claim 12, wherein upon flowing the carrier gas through the liquid precursor, a remaining amount of liquid precursor in the first volume falls from an initial temperature; and
wherein adjusting the one or more parameters of the ampoule further comprises:
adjusting the amount of energy provided to heat the remaining amount of liquid precursor in the first volume from an initial amount of energy provided to heat the liquid precursor to maintain the same vaporization rate of the liquid precursor as at the initial temperature.

14. The method of claim 12, wherein upon flowing the carrier gas through the liquid precursor, a remaining amount of liquid precursor in the first volume falls below a desired level; and
wherein adjusting the one or more parameters of the ampoule further comprises:
flowing the liquid precursor to the first volume until the liquid precursor is replenished within the first volume to the desired level.

15. The method of claim 14, further comprising:
controlling the temperature of the liquid precursor prior to flowing the liquid precursor to the first volume.

16. The method of claim 12, wherein the liquid precursor further comprises a solute and a solvent, and wherein upon flowing the carrier gas through the liquid precursor, a remaining amount of liquid precursor in the first volume falls below a desired concentration, and wherein adjusting one or more parameters of the ampoule further comprises:
flowing at least one of the solute or the solvent to the first volume until the liquid precursor is replenished to the desired concentration.

17. The method of claim 12, further comprising:
controlling the temperature of the carrier gas prior to flowing the carrier gas through the liquid precursor disposed in the first volume.

18. The method of claim 12, further comprising:
controlling the temperature of the liquid precursor within the first volume by separately providing energy to a portion of the first volume having the liquid precursor disposed therein and at least one of heating or cooling at least a remaining portion of the first volume.

19. The method of claim 12, further comprising:
monitoring the concentration of the gas mixture after the evaporated mixture exits the first volume; and
diluting the monitored concentration of the gas mixture prior to delivering the evaporated mixture to the process chamber if the concentration is above a desired concentration.

20. The method of claim 19, further comprising:
controlling the temperature of the liquid precursor prior to flowing the liquid precursor to the first volume;
controlling the temperature of the carrier gas prior to flowing the carrier gas to the first volume; and
controlling the temperature of the liquid precursor within the first volume by separately providing energy to a portion of the first volume having the liquid precursor disposed therein and at least one of heating or cooling to at least a remaining portion of the first volume.
